(19) United States
(12) Patent Application Publication
(10) Pub. No.: US 2025/0238188 A1
(43) Pub. Date: Jul. 24, 2025

(54) INFORMATION PROCESSING APPARATUS AND CONTROL METHOD

(71) Applicant: Lenovo (Singapore) Pte. Ltd., Singapore (SG)

(72) Inventors: Dadao Tian, Kanagawa (JP); Hidehisa Mori, Kanagawa (JP); Qian Wang, Kanagawa (JP); Hironari Nishino, Kanagawa (JP)

(73) Assignee: Lenovo (Singapore) Pte. Ltd., Singapore (SG)

(21) Appl. No.: 19/027,476

(22) Filed: Jan. 17, 2025

(30) Foreign Application Priority Data
Jan. 19, 2024 (JP) 2024-006938

(51) Int. Cl. G06F 3/16

(52) U.S. Cl. CPC G06F 3/162

(57) ABSTRACT

An information processing apparatus includes: a controller; and an audio system. The controller is configured to, when connection between the audio system and a sound source is detected, measure an output level of a test signal output to the sound source, and determine an output gain of a voice signal output from the audio system to the sound source based on the output level.

### CROSS-REFERENCE TO RELATED APPLICATIONS

This application claims priority to Japanese Patent Application No. 2024-006938 filed on Jan. 19, 2024, the contents of which are hereby incorporated herein by reference in their entirety.

### TECHNICAL FIELD

The present application relates to an information processing apparatus and a control method, for example, controlling an output level of a voice signal.

### BACKGROUND

An information processing apparatus such as a personal computer (PC) or a smartphone usually acquires user-desired content using a network and is capable of presenting the acquired content. The acquired content may include a voice. When a voice is presented in a public place, the presented voice may be propagated to the surroundings and may cause discomfort to others. In order to avoid this, a mountable sound source such as headphones or earphones may be used when reproducing a voice.

On the other hand, various sound sources have been widely used in the related art. An impedance varies greatly depending on the model of the sound source. For example, an average impedance of headphones is about 30 to 40Ω, but headphones having a high impedance of more than 100Ω are also widespread. Such a difference in impedance affects the output level of the voice signal provided from an information processing apparatus. For example, even in a case where the headphones are connected to the same information processing apparatus, the output level of the voice signal tends to be lower as the impedance of the headphones is higher. A voice reproduction apparatus that enables volume adjustment when a sound source that is an output destination of a voice is switched has been proposed.

For example, a voice reproduction apparatus described in Japanese Unexamined Patent Application Publication No. 2017-69925 includes a built-in speaker, an external output unit to which an external voice output device is connectable, a volume operation unit for a user to operate a volume of a voice signal, and a volume adjustment unit that adjusts the volume of the voice signal in response to a user operation of the volume operation unit, in which when an external voice device connects an output destination of the voice signal to the external output unit, the output destination of the voice signal is switched to the external output unit, and when the external voice output device is not connected to the external output unit, the output destination of the voice signal is switched to a built-in speaker, and different volume control is performed according to the output destination of the voice signal.

The voice reproduction apparatus disclosed in Japanese Unexamined Patent Application Publication No. 2017-69925 performs volume adjustment according to whether the output destination of the voice signal is switched to any of the external output unit and the built-in speaker depending on whether the voice output device is connected to the external output unit. In the volume adjustment, the acquired voice signal is amplified at an amplification factor according to a volume value input by the user operation. However, the fact that the impedance of the voice output device connected to the external output unit is diverse has not been sufficiently considered.

### SUMMARY

An information processing apparatus according to one or more embodiments of the present application includes a controller; and an audio system, in which the controller is configured to, when connection between the audio system and a sound source is detected, measure an output level of a test signal output to the sound source, and determine an output gain of a voice signal output from the audio system to the sound source based on the output level.

In the information processing apparatus, the controller may determine the output gain based on an impedance of the sound source corresponding to the output level, a rated power consumption of the sound source, and an internal resistance of the audio system.

In the information processing apparatus, the controller may determine a maximum voltage of the voice signal based on the impedance of the sound source, a maximum power consumption of the sound source and the internal resistance.

In the information processing apparatus, the test signal may have a frequency component having a frequency higher than an audible band.

The information processing apparatus may include a rectifier element configured to rectify the test signal and output a rectified signal; and a low pass filter configured to extract a low pass signal from the rectified signal, in which the controller may measure an output level of the low pass signal.

In the information processing apparatus, the low pass filter may include a resistance element and a power storage element in parallel with the controller, the controller may be configured to detect the output level after a predetermined time has elapsed from output start of the test signal, and the predetermined time may be set to a value larger than a product of a resistance value of the resistance element and an electrostatic capacity of the power storage element.

A control method according to one or more embodiments of the present application is a control method of an information processing apparatus including a controller and an audio system, the control method including: causing the controller to execute, when connection between the audio system and a sound source is detected, a step of measuring an output level of a test signal output to the sound source; and a step of determining an output gain of a voice signal output from the audio system to the sound source based on the output level.

One or more embodiments of present invention can adjust the output level of the voice signal according to the impedance of the sound source.

### BRIEF DESCRIPTION OF THE DRAWINGS

FIG. 1 is a perspective view illustrating an example of an appearance configuration of an information processing apparatus according to one or more embodiments.

FIG. 2 is a schematic block diagram illustrating a hardware configuration example of the information processing apparatus according to one or more embodiments.

FIG. 3 is a schematic block diagram illustrating a hardware configuration example relating to adjustment of an output level according to one or more embodiments.

FIG. 4 is a diagram illustrating an example of a setting table according to one or more embodiments.

FIG. 5 is a diagram illustrating a setting example of impedance and a maximum output voltage for each model of a sound source.

FIG. 6 is a flowchart exemplifying volume control according to one or more embodiments.

FIG. 7 is a circuit diagram illustrating a configuration example of a processing circuit according to one or more embodiments.

FIG. 8 is a diagram illustrating an example of a change in output level over time that is detected.

FIG. 9 is a diagram illustrating another example of a change in output level over time that is detected.

### DETAILED DESCRIPTION

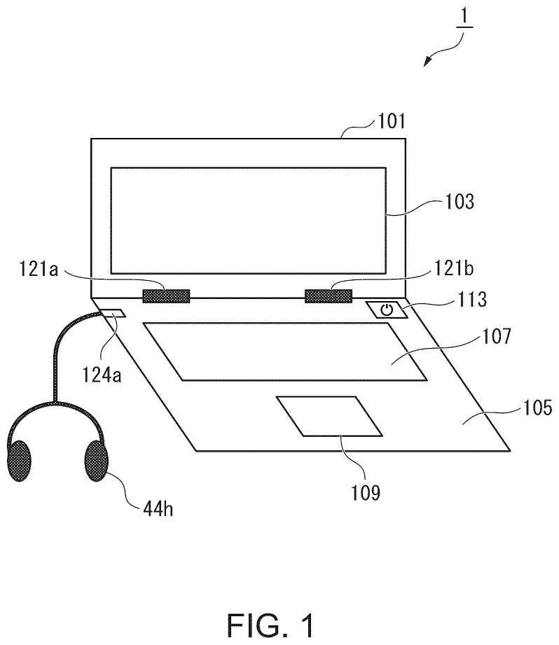

Hereinafter, embodiments of the present application will be described with reference to the drawings. First, an outline of an information processing apparatus 1 according to one or more embodiments will be described. FIG. 1 is a perspective view illustrating an example of an appearance configuration of the information processing apparatus 1 according to one or more embodiments. In the example of FIG. 1, the information processing apparatus 1 is configured as a laptop personal computer (laptop PC).

The information processing apparatus 1 includes a first chassis 101 and a second chassis 105, and the first chassis 101 and the second chassis 105 are coupled to each other by using hinge mechanisms 121a and 121b. The hinge mechanisms 121a and 121b are fixed to one side of each of the first chassis 101 and the second chassis 105. One of the first chassis 101 and the second chassis 105 is rotatable relative to the other with one side of the first chassis 101 and the second chassis 105 as a rotation axis. That is, an angle θ (in the present application, referred to as an “opening angle”) formed between a main surface of the first chassis 101 and a main surface of the second chassis 105 is variable.

A display 103 is disposed on the main surface of the first chassis 101 and occupies a large part of the main surface. A keyboard 107, a touch pad 109, and a power button 113 are disposed on the main surface of the second chassis 105. With such an arrangement, the information processing apparatus 1 is used in a state where the first chassis 101 and the second chassis 105 are open. The open state is a state where one of the main surface of the first chassis 101 and the main surface of the second chassis 105 is open without being shielded from the other. In the open state, the opening angle θ is typically in a range of 90° to 180°.

An audio terminal 124a is installed on a side surface of the second chassis 105. The audio terminal 124a is attachably and detachably connected to an input/output terminal of the voice device by an external force. The audio terminal 124a has a shape that is capable of being fitted to the input/output terminal of the voice device, and is capable of inputting and outputting the voice signal of the information processing apparatus 1 in a state of being fitted to the input/output terminal. In the example of FIG. 1, the audio terminal 124a has an audio jack. The voice device is a headphone 44h and includes an audio plug as the input/output terminal. The audio plug is inserted into a cavity portion of the audio terminal 124a, and a voice signal is input to and output from the audio terminal 124a.

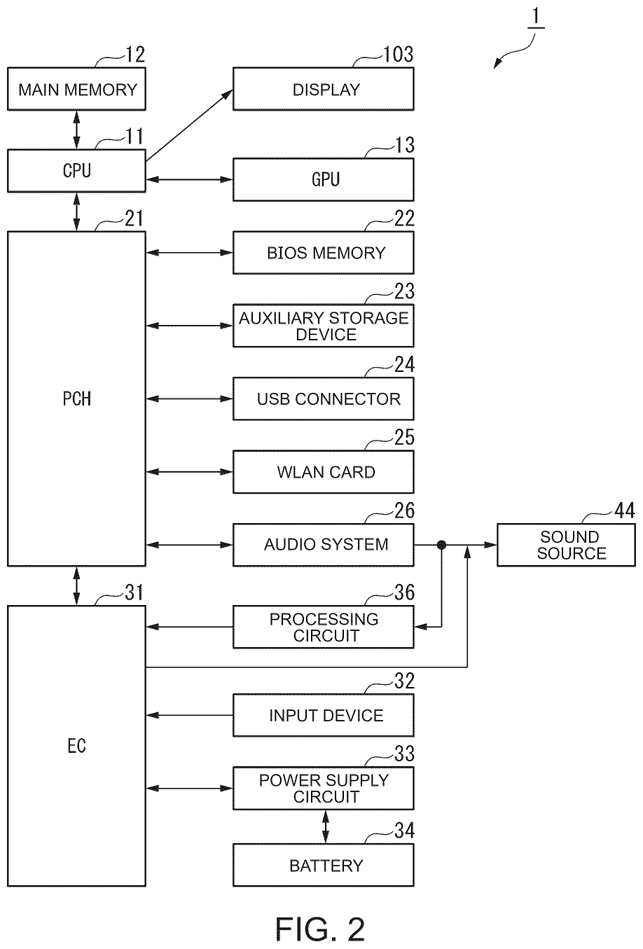

The voice device includes a sound source 44 (FIG. 2). The sound source 44 generates a sound in accordance with the voice signal input to the own part. The sound source 44 includes an electroacoustic transducer (for example, a speaker) that generates mechanical vibration in response to the voice signal that is an electric signal. The voice device may include a sound reception element (for example, a microphone) that receives a sound arriving at the own part. The voice device may separately include the sound reception element from the sound source 44, or the sound reception element may be shared as the sound source 44. The number of sound sources 44 may be one or two or more. The sound source 44 may be configured as a mountable device (wearable device) that is mounted being in contact with or in close proximity to each ear. As the sound source 44 that can be mounted on the human body, the headphone 44h and an earphone are typical.

In general, the electrical impedance of the sound source 44 (in the present application, may be simply referred to as “impedance”) greatly varies depending on the model. When the voice signal is output to the sound source, an output level of the voice signal provided to the sound source varies depending on the impedance. As the impedance of the sound source 44 is higher, the output level of the voice signal from the signal source tends to be lower. As will be described later, the information processing apparatus 1 measures the impedance of the sound source 44 when the connection to the sound source is detected. The information processing apparatus 1 determines that the output level of the voice signal is higher as the measured impedance is higher. As a result, a difference in volume between the models is reduced regardless of the impedance of the sound source 44.

Next, a hardware configuration example of the information processing apparatus 1 according to one or more embodiments will be described. FIG. 2 is a schematic block diagram illustrating the hardware configuration example of the information processing apparatus 1 according to one or more embodiments. The information processing apparatus 1 includes a CPU 11, a main memory 12, a graphic processing unit (GPU) 13, a display 103, a platform controller hub (PCH) 21, a basic input output system (BIOS) memory 22, an auxiliary storage device 23, a universal serial bus (USB) connector 24, a wireless local area network (WLAN) card 25, an audio system 26, an embedded controller (EC) 31, an input device 32, a power supply circuit 33, a battery 34, and a processing circuit 36.

The CPU 11 is a processor that is a core of a system device provided in the information processing apparatus 1. The CPU 11 is a processor that enables the execution of various arithmetic processing instructed by commands written in various programs. The CPU 11 executes processing instructed by various programs, such as an operating system (OS), BIOS, firmware, and an application program (referred to as an “app” in the present application).

The CPU 11 executes the OS to provide functions, such as resource management, execution management of various programs, input/output control, and file management in the computer system that is a core of the information processing apparatus 1, that is, the host system. Executing the processing instructed by a command written in a program may be referred to as “execution of the program” or “executing the program”.

The main memory 12 is a writable memory that is used as a reading area of the execution program of the processor or as a work area in which processing data of the execution program is written. The main memory 12 is configured with, for example, a plurality of dynamic random access memory (DRAM) chips. The execution program includes the OS, various drivers for operating hardware such as peripheral devices, various services/utilities, applications, and the like.

The GPU 13 is mainly a processor that executes real-time image processing. The GPU 13 processes a drawing command from the CPU 11 and writes drawing information obtained by the processing into a video memory (not illustrated). The GPU 13 reads out the drawing information from the video memory, and outputs the drawing information as display data indicating the drawing information to the display 103 via the CPU 11 (image processing). The drawing information notified to the display 103 constitutes a display screen.

The CPU 11 executes a graphic driver on the OS to control the operation of the GPU 13 and realize image processing instructed by the OS, the application, and other programs. The number of GPUs 13 is not limited to one and may be plural. The GPU 13 may share some processing with the CPU 11 and execute parallel arithmetic processing other than image processing.

The CPU 11, the main memory 12, and the PCH 21 form a computer system, that is, a host system, which is the core of the information processing apparatus 1. In other words, the computer system of the information processing apparatus 1 is configured to include a system device as hardware and software such as the OS and a schedule task.

The display 103 displays the display screen based on the display data output from the CPU 11. For example, the display 103 may be any display, such as a liquid crystal display (LCD) or an organic light emitting diode (OLED) display.

The PCH 21 includes one or a plurality of bus controllers, and is connectable to a plurality of devices so that various types of data can be input and output. The bus controller may be, for example, any one of a USB, a serial advanced technology attachment (ATA), a serial peripheral interface (SPI) bus, a peripheral component interconnect (PCI) bus, a PCI-Express bus, a low pin count (LPC), and the like, or a combination of any one thereof. For example, the plurality of devices that are the connection destinations correspond to the BIOS memory 22, the auxiliary storage device 23, the USB connector 24, the WLAN card 25, the audio system 26, and the EC 31.

The BIOS memory 22 stores firmware for controlling the operation of the BIOS, the EC 31, and other devices, and the like. The BIOS is firmware for performing basic input and output of the system device. In the present application, the BIOS may also include firmware defined in accordance with a specification specified in Unified Extensible Firmware Interface (UEFI). The BIOS memory 22 is configured to include an electrically rewritable nonvolatile memory. As such a nonvolatile memory, for example, an electrically erasable programmable read only memory (EEPROM), a flash read only memory (ROM), or the like is available.

The auxiliary storage device 23 continuously stores various types of data. The data to be stored includes various programs that may be executed by the CPU 11 and the GPU 13, parameters, data used for various types of processing, and data acquired by the various types of processing. The auxiliary storage device 23 may be, for example, any of a hard disk drive (HDD) or a solid state drive (SSD). The auxiliary storage device 23 is configured to include various nonvolatile memories. For example, a flash memory is used as the nonvolatile memory. The various programs may include, for example, any one of the OS, a driver, firmware, an application, and the like, or a combination of any one thereof.

The USB connector 24 is a connector for connecting various peripheral devices using USB.

The WLAN card 25 connects to a wireless LAN or another network via the wireless LAN, and can wirelessly transmit and receive various types of data between the connection destination and a device.

The audio system 26 can execute acquisition, recording, reproduction, and output of voice data under the control of the host system. The audio system 26 converts, for example, an analog voice signal input from a microphone (not illustrated) connected to the own part into digital voice data (analog-to-digital (AD) conversion). The audio system 26 reads out the voice data designated from a storage medium in which the voice data is stored in advance. The audio system 26 acquires the voice data designated from another device. The storage medium that is an acquisition source of the voice data may be a storage medium provided in the audio system 26 or may be the auxiliary storage device 23 or another device. The audio system 26 stores the acquired voice data in the storage medium. The audio system 26 converts the acquired digital voice data into an analog voice signal (digital-to-analog (DA) conversion). When presenting the voice, the audio system 26 outputs the converted analog voice signal to the sound source 44. The audio terminal 124a (FIG. 1) may be installed in the audio system 26.

The processing of the audio system 26, that is, acquisition, recording, reproduction, and output are instructed by commands described in an application and other programs executed by the host system. The audio system 26 may include one or both of a coder that encodes the acquired voice data using a predetermined voice encoding method and a decoder that decodes the acquired digital voice data using a predetermined voice decoding method. The encoder and the decoder may be configured as a single integrated codec.

The information processing apparatus 1 may incorporate a microphone and a speaker (not illustrated), or may be separate from the microphone and the speaker. The built-in speaker may also be selected by the user operation as one of the sound sources 44.

The EC 31 is a one-chip microcomputer that monitors and controls the status of various devices (peripheral devices, sensors, and the like) regardless of the operation state of the host system that forms the core of the information processing apparatus 1. The EC 31 includes a ROM, a plurality of channels of analog-to-digital (A/D) input terminals, a digital-to-analog (D/A) output terminal, a timer, and an input/output interface (not illustrated), in addition to a processor that is separate from the CPU 11 and the RAM that is separate from the main memory 12. The EC 31 executes predetermined firmware to exhibit the function of the firmware.

The input device 32, the power supply circuit 33, the processing circuit 36, and other devices are connected to the input/output interface of the EC 31 in a wired manner. The EC 31 enables the control of the operation of the devices. The input/output interface may be connected to various devices such that data is capable of being transmitted and received wirelessly. The input device 32 may be wirelessly connected to the EC 31 using the input/output interface. The input/output interface may implement, for example, wireless connection using a short-range wireless communication method defined in IEEE 802.15.1.

The EC 31 monitors the use environment of the information processing apparatus 1 based on various electric signals input to the own part. The EC 31 determines whether the sound source is connected based on a potential of a signal cable that connects the audio system 26 and the sound source 44. Here, for example, the EC 31 can detect a potential difference between a reference potential line (ground line) forming a part of the signal cable and the signal line, and determine whether the sound source is connected, depending on whether the detected potential difference is equal to or greater than a reference value of a predetermined potential difference.

When it is determined that the sound source 44 is connected, the EC 31 measures the impedance of the sound source 44. Here, the EC 31 causes the audio system 26 to output a test signal to the sound source 44. In this case, the EC 31 measures an output level obtained by passing the test signal output from the audio terminal 124a to the sound source 44 through the processing circuit 36. The EC 31 can calculate the impedance of the sound source 44 based on the measured output level and the internal impedance of the audio system 26. The EC 31 notifies the host system of the calculated impedance.

The host system determines a gain of the voice signal output from the audio system 26 to the sound source 44 to be higher as the impedance notified from the EC 31 is higher. Therefore, as the impedance of the sound source 44 is higher, the output level of the voice signal is higher.

The input device 32 detects an operation of the user and outputs an operation signal generated in response to the detected operation to the EC 31. For example, the keyboard 107 and the touch pad 109 correspond to the input device 32. The input device 32 may further include a touch sensor. The touch sensor may be configured as a touch panel by overlapping the display 103 forming the display unit.

The power supply circuit 33 supplies power required for the operation of each device provided in the information processing apparatus 1 in accordance with the control of the EC 31. The device that is a power supply destination includes not only the system device but also a peripheral device. In addition, the peripheral device connected to the USB connector 24 can also be a power supply destination. An operation voltage of the device may vary for an individual device. The various devices may also include a device that requires a plurality of levels of voltages. The plurality of levels of voltages may include a reference voltage in addition to the operation voltage.

The power supply circuit 33 includes a converter that converts a voltage of the power supplied to the own part and a power supply device that supplies, to the battery 34, the power of which the voltage is converted. In a case where power is supplied from an AC adapter (not illustrated), the power supply device supplies the power remaining without being consumed in each device to the battery 34. In a case where power is not supplied from the AC adapter or in a case where the power supplied from the AC adapter is insufficient for the power consumption consumed by each device, the power discharged from the battery 34 is supplied to each device as the operation power.

As the converter, for example, one or a plurality of DC/DC converters are used. The plurality of DC/DC converters may be used for each converted voltage. In addition, a first type converter that is a part of the plurality of DC/DC converters may be connected to a device of which an operation state may vary depending on the system device or the operation mode of the system device. The first type converter may control the power to be supplied based on the operation mode notified from the EC 31. A second type converter, which is a part of the plurality of DC/DC converters, may be connected to a device that operates regardless of the operation mode of the system device. The second type converter may be able to regularly supply a constant amount of power.

Examples of the device to be operated regardless of the operation mode of the system device include the EC 31, the processing circuit 36, and the sound source 44.

The battery 34 stores the power supplied from the power supply circuit 33 based on the control of the power supply circuit 33. The battery 34 discharges a part of the stored power to the power supply circuit 33. A secondary battery is used as the battery 34. The secondary battery is a storage battery capable of both charging and discharging. The secondary battery is, for example, a lithium ion battery.

The AC adapter converts the alternating-current power supplied from an external power supply into direct-current power having a constant voltage and supplies the converted power to the power supply circuit 33. The AC adapter includes a mounting tool that enables attachment to and detachment from a chassis of the information processing apparatus 1 including the power supply circuit 33. The mounting tool includes an interface capable of transmitting both power and data in accordance with a predetermined standard. As the predetermined standard, it is possible to use, for example, USB Type-C.

The processing circuit 36 is connected between the audio system 26 and the EC 31, and includes a rectifier element that rectifies the test signal input from the audio system 26, and a low-pass circuit that extracts a low frequency component of the rectified test signal. The processing circuit 36 outputs the output signal output from the low-pass circuit to the EC 31. The EC 31 can detect the potential of the output signal input from the processing circuit 36 as the output level of the test signal supplied to the sound source 44.

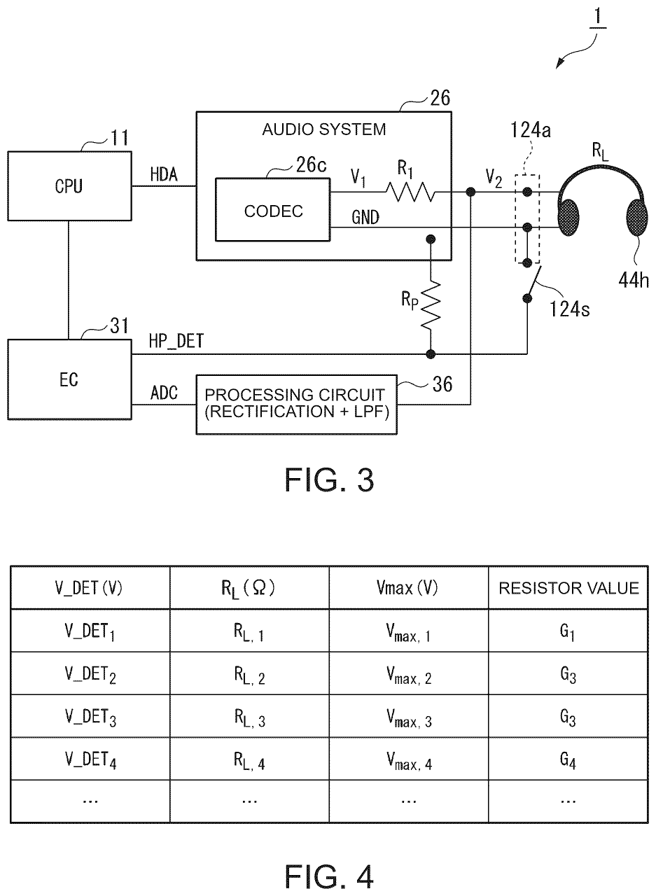

Next, a method of adjusting the output level of the voice signal will be described in more detail. FIG. 3 is a schematic block diagram illustrating a hardware configuration example relating to adjustment of the output level according to one or more embodiments. In the example of FIG. 3, a codec 26c is built in the audio system 26. As an example of the sound source 44, the headphone 44h is used, and a case where the headphone 44h is attached to and detached from the audio terminal 124a is assumed. In a state where the headphone 44h is connected to the audio terminal 124a, a speaker corresponding to each ear of the headphone 44h is electrically connected to the codec 26c by using a signal cable of a voice channel corresponding to each ear. The codec 26c is connected to the CPU 11 and operates under the control of the CPU 11. The codec 26c is connected to the CPU 11, for example, according to a high definition audio (HDA) standard. The codec 26c converts the digital voice data input from the CPU 11 into an analog voice signal. The analog voice signal is transmitted to the audio terminal 124a by using one system of the signal cable for each voice channel. One system of the signal cable includes two conductive wires. One of the two conductive wires is connected to a reference potential point (GND) to function as a reference potential line, and the other conductive wire functions as a signal line that transmits a substantial voice signal. The voice signal represents a voice waveform by a change in potential over time. In FIG. 3, R₁ indicates an internal resistance of the audio system 26. The audio system 26 may include an amplifier (not illustrated) that amplifies the voice signal, and the volume may be adjustable. In general, the higher an amplification factor of the amplifier for the voice signal, the smaller the internal resistance R₁ is.

The EC 31 has two voice signal terminals. A signal line connected to one voice signal terminal HP_DET is electrically connected to the reference potential line and one end of a switch 124s via a pull-up resistor Rₚ. The other end of the switch 124s is electrically connected to the other end of the reference potential line. The switch 124s is a mechanical switch and is built in or adjacent to the audio terminal 124a. When the audio plug is inserted into the audio terminal 124a, pieces of the switch 124s come into contact with each other at both ends and are short-circuited (switch ON). In this state, when the audio plug is separated from the audio terminal 124a, the pieces of the switch 124s are separated from both ends and insulated (switch OFF). Therefore, the EC 31 monitors the potential of the voice signal terminal HP_DET and the signal line. The EC 31 determines whether the measured potential is equal to or less than a predetermined detection threshold value in a state where the voice signal is not output to the headphone 44h. When an absolute value of the potential difference of the EC 31 is equal to or less than the detection threshold value, the EC 31 can determine that the headphone 44h is connected to the audio terminal 124a. When the absolute value of the potential difference of the EC 31 exceeds the reference value, the EC 31 can determine that the headphone 44h is separated from the audio terminal 124a. In a case where the headphone 44h is not connected, the potential at the voice signal terminal HP_DET is significantly higher than the reference potential.

When it is determined that the headphone 44h is connected, EC 31 notifies the CPU 11 of the connection to the headphone 44h. When the connection to the headphone 44h is notified from the EC 31, the CPU 11 outputs a voice signal having a known characteristic as a test signal to the audio system 26 for each voice channel. The test signal output from the codec 26c is attenuated by the internal resistance R₁, is supplied to the headphone 44h via the audio terminal 124a, and is supplied to the EC 31 via the processing circuit 36.

In the EC 31, an amplitude V₁ and a frequency f₁ of the output voltage of the test signal are set in advance. As the frequency f₁, a voice signal having a frequency component of a frequency (for example, 20.5 kHz) higher than an audible frequency (typically, 20 Hz to 20 kHz) may be applied. The test signal may be a sine wave of the frequency. As a result, even if the voice based on the test signal is presented to the user wearing the headphone 44h, the presented voice is not perceived. Strictly speaking, a difference in impedance occurs between the voice signal having a frequency component of an audible frequency and the test signal having a higher frequency component. However, the frequency dependence of the impedance is not as remarkable as the dependence on the structure of the sound source.

The processing circuit 36 includes a rectifier element and a low pass filter (LPF). The rectifier element rectifies the test signal input from the audio system 26 and outputs the rectified signal obtained by the rectification to the low pass filter. The low pass filter has a low-pass characteristic of allowing a larger amount of passage of a frequency component having a lower frequency among the frequency components of the rectified signal input from the rectifier element, and outputs the rectified signal after the passage as a low pass signal to the EC 31. The low-pass characteristics can also be regarded as temporal smoothing. The low pass signal may be set to have low-pass characteristics such that a direct current component of the test signal after rectification is mainly remained. The EC 31 measures a potential V_DET of the test signal input from the processing circuit 36. The measured potential V_DET corresponds to an output level V₂ of the test signal output from the audio system 26. In the example of FIG. 3, the test signal is input to an input terminal of an AD converter (ADC) provided in the EC 31 and is converted into a digital signal. The potential V_DET indicating a real value transmitted by the converted digital signal is obtained.

The EC 31 can estimate the impedance R_{L} of the headphone 44h based on the measured output level V₂, the preset internal resistance R₁, and output voltage V₁ of the audio system 26. The impedance R_{L} is obtained by multiplying the internal resistance R₁ by a ratio V₂/(V₁−V₂) of the output voltage V₁ to the output level V₂ with respect to the output level V₂. This relationship is due to the fact that the ratio of the output voltage V₁ to the output level V₂ corresponds to a ratio of the total impedance R₁+R_{L} obtained by combining the internal resistance R₁ and the impedance R_{L} to the impedance R_{L}.

The EC 31 notifies the CPU 11 of the calculated impedance R_{L}.

A setting table illustrating a relationship between the impedance of the sound source and the output gain corresponding to the output voltage after the adjustment is set in advance in the CPU 11. The CPU 11 refers to the setting table, determines the output gain corresponding to the impedance R_{L} notified from the EC 31, and sets the determined output gain in the audio system 26. The output gain corresponds to a ratio of an output voltage of the voice signal to be output to a predetermined reference output voltage (hereinafter, referred to as a “reference output voltage”) in the codec 26c. The audio system 26 multiplies a signal value of each sample forming the voice signal converted by the DA conversion by the set output gain. The audio system 26 outputs the voice signal including the multiplication value obtained by the multiplication as the voice signal after the volume adjustment to the audio terminal 124a.

In the setting table, a maximum output voltage may be described in association with the impedance. In that case, the CPU 11 refers to the setting table and further specifies the maximum output voltage corresponding to the impedance R_{L} notified from the EC 31. The CPU 11 determines the output gain corresponding to the default output voltage specified as described above, and sets the determined output gain in the audio system 26. On the other hand, the CPU 11 sets the specified maximum voltage in the audio system 26. The audio system 26 adjusts the amplitude of the voice signal such that the voltage value indicating the voice signal after volume adjustment does not exceed the set maximum voltage. The audio system 26 outputs the voice signal after the amplitude adjustment to the audio terminal 124a. As a result, the supply of the voice signal accompanied by the power exceeding the maximum output voltage to the headphone 44h is avoided.

The power consumption P by the voice signal supplied to the headphone 44h and the output voltage U from the codec 26c have a relationship represented by Expression (1). According to Equation (1), the output voltage U corresponds to a multiplication value obtained by multiplying the sum of the internal resistance R₁ of the audio system 26 and the impedance R_{L} of the headphone 44h by a square root of the ratio of the power consumption P to the impedance R_{L}. Here, the audio terminal 124a can also be regarded as an output point that divides the voltage of the voice signal output from the codec 26c by the ratio of the internal resistance R₁ and the impedance R_{L}. The square root of the ratio of the power consumption P to the impedance R_{L} corresponds to a current I supplied to the headphone 44h. The default output voltage corresponds to a voltage value U calculated using Expression (1) with respect to the rated power consumption P of the headphone 44h.

The default output gain is calculated by dividing the default output voltage U corresponding to the impedance R_{L} of the headphone 44h by the reference output voltage corresponding to the reference impedance. As described above, the impedance R_{L} is determined based on the output voltage V₁ of the test signal, the measured output level V₂, and the internal resistance R₁ of the audio system 26. The default output gain is determined based on the impedance R_{L} determined by the measured output level V₂, the rated power consumption P of the headphone 44h, and the internal resistance R₁ of the audio system 26. The maximum voltage corresponds to the voltage value U calculated using Expression (1) with respect to the maximum power consumption P allowed for the headphone 44h. That is, the maximum voltage is determined based on the impedance R_{L} determined by the measured output level V₂, the maximum power consumption P of the headphone 44h, and the internal resistance R₁ of the audio system 26.

$$U = ( {R}_{1} + {R}_{L} ) \times \sqrt{\frac{P}{{R}_{L}}} \qquad ( 1 )$$

FIG. 4 is a diagram illustrating an example of the setting table according to one or more embodiments. The setting table illustrated in FIG. 4 has a set of an output level V_DET (unit: V), an impedance R_{L} (unit: Q), a maximum output voltage Vₘₐₓ (V), and a register value, and is configured to include these for each output level V_DET. The output level V_DET corresponds to the output level V₂. Under a certain internal resistance R₁ and output voltage V₁, as the output level V_DET increases, the impedance R_{L} increases, and the rate of increase in the impedance R_{L} with respect to the increase in the output level V_DET also increases. In addition, as the output level V_DET increases, the maximum output voltage Vₘₐₓ and the output gain G also increase. As the output level V_DET increases, the increase rate of the output gain G with respect to the increase of the output level V_DET also tends to increase, but is not as remarkable as the increase rate of the impedance R_{L}. The maximum output voltage Vₘₐₓ is roughly proportional to the output gain G.

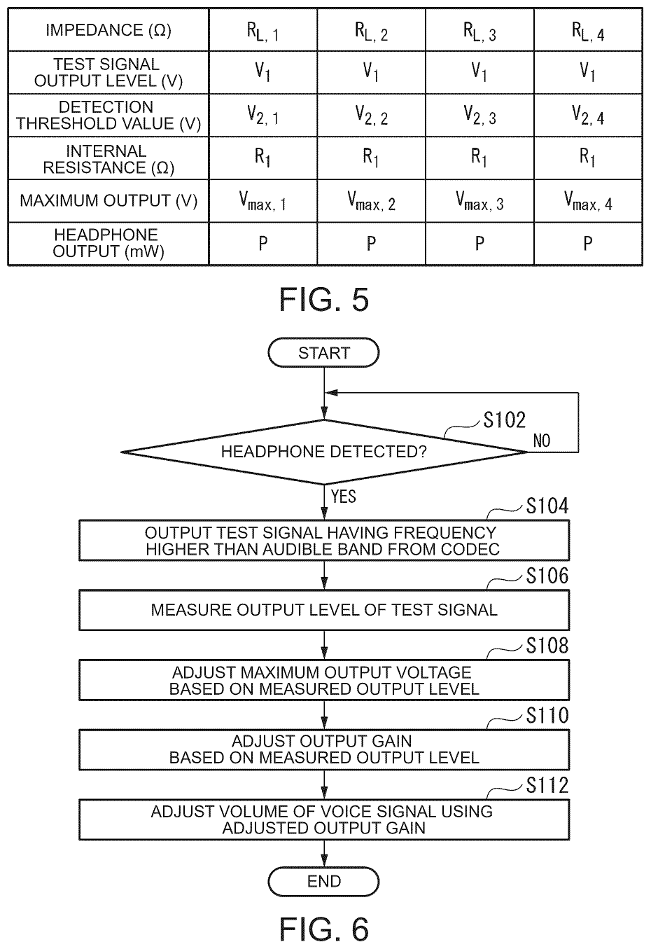

FIG. 5 is a diagram illustrating a setting example of the impedance and the maximum output voltage for each model of the headphone 44h. Four types of headphones having different structures were set as measurement targets. An output level of the test signal and a headphone output (power consumption) were set to V₁ and P, respectively, which were constant regardless of the model. In addition, the internal resistance R₁ of the audio system 26 was set to be constant. The measured impedances R_{L,1} to R_{L,4} vary greatly depending on the model. A difference of 10 times or more occurred between the minimum value R_{L,1} and the maximum value R_{L,4}. In the example of FIG. 5, the detection threshold value differs for each model, but the detection threshold value may be a common constant value regardless of the model.

The rated power consumption may be common regardless of the model of the headphone 44h as described above, or may vary depending on the model. The maximum output voltage may differ depending on the model of the headphone 44h as described above, or may be common regardless of the model. In a case where one or both of the rated power consumption and the maximum output voltage vary depending on the model, a setting table may be set in the CPU 11 or the audio system 26 in advance for each model. When the headphone 44h is connected to the audio system 26, the headphone 44h may output a notification signal indicating model information indicating a model of the headphone 44h to the EC 31, and the EC 31 may notify the CPU 11 of the model information indicated by the notification signal. The CPU 11 can select a setting table corresponding to the notified model information and determine the output gain and the maximum output voltage by using the selected setting table.

Next, an example of volume control according to one or more embodiments will be described. FIG. 6 is a flowchart illustrating the volume control according to one or more embodiments.
(Step S102) The EC 31 monitors a voltage of the voice signal output from the audio terminal 124a, and determines whether the headphone 44h is connected based on the voltage. When it is determined that the headphone is connected (headphone detection: YES in step S102), the processing proceeds to step S104. When it is determined that the headphone is not connected (headphone detection: NO in step S102), the processing of step S102 is repeated.
(Step S104) The CPU 11 outputs a test signal having a frequency higher than the audible band from the codec 26c provided in the audio system 26 to the audio terminal 124a.
(Step S106) The EC 31 measures an output level of the test signal input from the audio terminal 124a via the processing circuit 36. The measured output level depends on the impedance of the headphone 44h. The EC 31 notifies the CPU 11 of the measured output level.
(Step S108) The CPU 11 refers to the setting table, determines the maximum output voltage corresponding to the output level notified from the EC 31, and sets the determined maximum output voltage as the maximum output voltage of the voice signal output from the audio system 26.
(Step S110) The CPU 11 refers to the setting table, determines the output gain corresponding to the output level notified from the EC 31, and sets the determined output gain as the output gain in the audio system 26.
(Step S112) The audio system 26 adjusts the volume of the voice signal decoded by the codec 26c based on the set output gain, and outputs the voice signal after the volume is adjusted to the headphone 44h via the audio terminal 124a. Then, the processing in FIG. 6 ends.

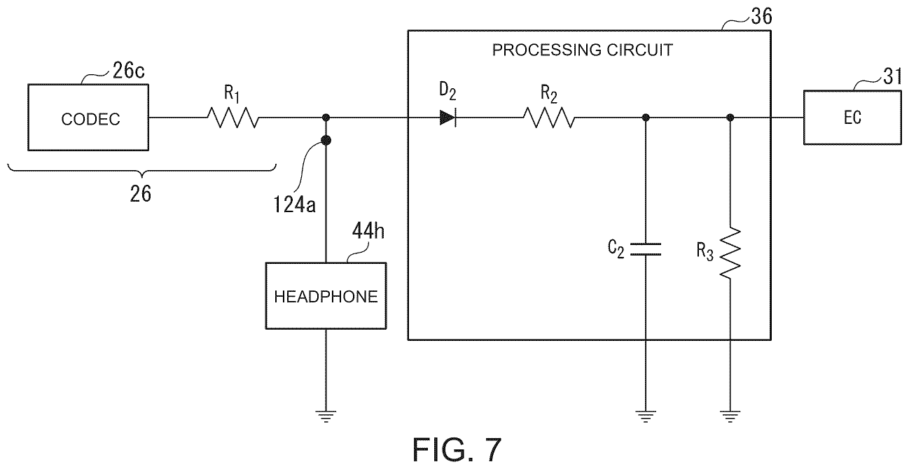

Next, a configuration example of the processing circuit 36 according to one or more embodiments will be described. FIG. 7 is a circuit diagram illustrating a configuration example of the processing circuit 36 according to one or more embodiments. In FIG. 7, a reference signal line is not illustrated. In addition, it is assumed that the headphone 44h is connected to the audio terminal 124a.

The processing circuit 36 includes a rectifier element D₂, resistance elements R₂ and R₃, and a power storage element C₂. The rectifier element D₂ and the resistance element R₂ are connected in series. The resistance element R₂ is connected in series with each of the resistance element R₃ and the power storage element C₂. The resistance element R₂ and the power storage element C₃ are connected in parallel with each other and are also connected in parallel with the EC 31.

The rectifier element D₂ rectifies the voice signal input from the audio system 26, allows a forward direction component having a positive potential to pass, and blocks a backward direction component having a negative potential. The rectifier element D₂ outputs the forward direction component as the rectified voice signal to one end of the resistance element R₂. The rectifier element D₂ is, for example, a diode.

In the resistance element R₂, the voice signal after rectification is input from the rectifier element D₂ to one end thereof. The resistance element R₂ allows the input voice signal to pass through the electric resistance value R₂ and outputs the voice signal from the other end to one end of the power storage element C₂, one end of the resistance element R₃, and the input end of the EC 31, respectively.

The voice signal is input from the other end of the resistance element R₂ to one end of each of the power storage element C₂ and the resistance element R₃. The other end of each of the power storage element C₂ and the resistance element R₃ is electrically connected to the reference potential point. Therefore, both the power storage element C₂ and the resistance element R₃ form an RC circuit in parallel with the EC 31.

With this configuration, the processing circuit 36 functions as a low pass filter having low-pass characteristics with respect to the forward direction component obtained by the rectifier element D₂. The electric capacity C₂ and the electric resistance value R₃ are set such that a time constant, which is a product of the electric capacity C₂ of the power storage element and the electric resistance value R₃ of the resistance element, is sufficiently larger than a reciprocal of the frequency of the main component of the test signal. The forward direction component obtained by the rectifier element D₂ is temporally smoothed, and the direct current component is mainly supplied to the EC 31.

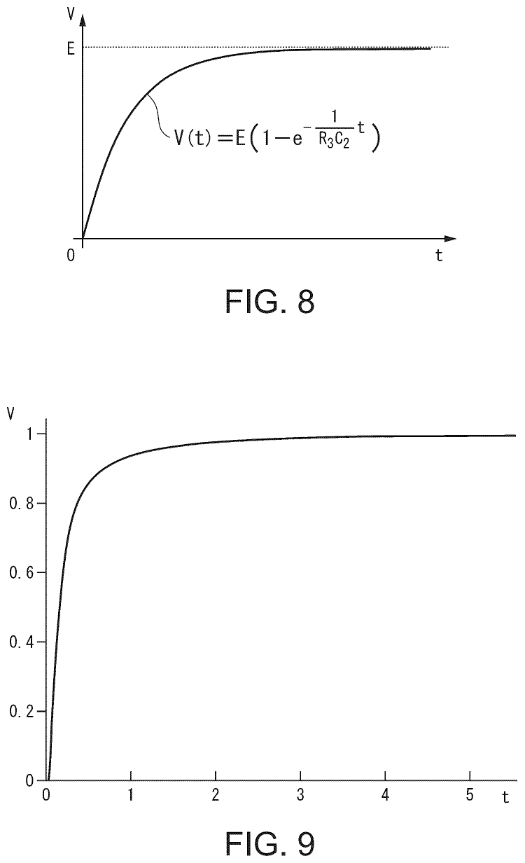

An output level V(t) of the test signal output from the codec 26c with a constant amplitude increases with the elapse of time and gradually approaches a certain value E. As illustrated in FIG. 8, the output level V(t) is E (1−e_{-1/R3C2}), and a difference from E is exponentially attenuated with a time constant R₃C₂. FIG. 9 illustrates the output level V(t) in a case where E=1 V, R₃=300 kΩ, and C₂=100 nF. The output level V(t) is initially 0 V and does not immediately reach E=1 V immediately after the output of the test signal. 0.9 V is obtained when the elapsed time t from the start of the output of the test signal is 0.69 ms. Therefore, the EC 31 detects the output level after a time (for example, 2.3R₃C₂ or more) sufficiently longer than the time constant R₃C₂ has elapsed from the start of the output of the test signal.

In the above description, a case where the CPU 11 refers to the setting table to determine the output gain or the maximum power corresponding to the measured output level is described as an example, but the present invention is not limited thereto. The CPU 11 may calculate the output gain or the maximum power from the output level using a preset calculation formula. In addition, in the above description, a case where the CPU 11 (that is, the host system) and the EC 31 are used as the controller that executes the volume control and share the processing is described as an example, but the present invention is not limited thereto. Any one of the host system or the EC 31 may collectively execute the processing related to the volume control without sharing the processing.

In addition, in the above description, a case where the information processing apparatus 1 is configured as a laptop PC is described as an example, but the present invention is not limited thereto. The information processing apparatus 1 may be configured as, for example, a mobile phone or a tablet terminal device. In addition, a separate sound source may be incorporated into the information processing apparatus 1 instead of the detachable sound source 44 using the audio terminal 124a. In that case, the host system disconnects the connection to the built-in sound source when the connection of the sound source 44 to the audio terminal 124a is detected. The host system reconnects to the built-in sound source when the host system detects the separation of the sound source 44 from the audio terminal 124a.

As described above, the controller (for example, the host system or the EC 31) and the audio system 26 according to one or more embodiments are provided. The controller measures the output level of the test signal output to the sound source 44 when the connection between the audio system 26 and the sound source 44 is detected. The controller determines the output gain of the voice signal output from the audio system to the sound source 44 based on the measured output level.

The controller can determine the output gain based on, for example, the impedance of the sound source 44 corresponding to the output level, the rated power consumption of the sound source 44, and the internal resistance of the audio system.

With this configuration, when the sound source 44 is connected to the audio system 26, the output level of the test signal output to the sound source 44 is measured. The output gain of the voice signal output from the audio system 26 to the sound source 44 is determined based on the measured output level. Here, the controller determines the output gain of the voice signal to be larger as the measured output level is higher. Since the output level is compensated to be lower as the impedance of the sound source 44 connected to the audio system 26 is higher, the difference in the output level is reduced depending on the type of the sound source 44.

In addition, the controller may determine the maximum voltage of the voice signal based on the impedance of the sound source 44, the maximum power consumption of the sound source and the internal resistance.

The audio system 26 controls the voltage of the voice signal output from the own part not to exceed the maximum voltage, so that the input of the voice signal having an excessive voltage exceeding the maximum voltage is avoided for the sound source 44. Therefore, the sound source 44 is protected.

The test signal may have a frequency component having a frequency higher than the audible band.

Even if the sound is presented based on the test signal by wearing the sound source 44, the listener does not perceive the presented sound. Therefore, the listener does not have to feel discomfort due to the presentation of the sound based on the test signal.

The information processing apparatus 1 may include a rectifier element that rectifies the test signal and outputs a rectified signal, and a low pass filter that extracts a low pass signal from the rectified signal. In addition, the controller may measure an output level of the low pass signal.

With this configuration, a direct current component of the rectified signal obtained by rectifying the test signal is obtained as a main component, and an output level thereof is measured. Therefore, the power of the test signal can be estimated with the output level measured by the simple configuration.

The low pass filter may include a resistance element and a power storage element in parallel with the controller. The controller may detect the output level after a predetermined time from the output of the test signal. The predetermined time is set to a value larger than a product of the resistance value of the resistance element and the electrostatic capacity of the power storage element. Since the output level that is close to a certain value is detected after a sufficient time has elapsed from the start of the output of the test signal, the output level of the direct current component is detected more accurately than immediately after the start of the output of the test signal.

Although embodiments of the present invention have been described in detail with reference to the drawings, the specific configurations are not limited to the above-described embodiments, and the present application includes designs and the like within a scope not departing from the spirit of the invention. It is possible to optionally combine the configurations described in the above-described embodiments.

### DESCRIPTION OF SYMBOLS

1 information processing apparatus
11 CPU
12 main memory
13 GPU
21 PCH
22 BIOS memory
23 auxiliary storage device
24 USB connector
25 WLAN card
26 audio system
26c codec
31 EC
32 input device
33 power supply circuit
34 battery
36 processing circuit
44 sound source
44h headphone
101 first chassis
103 display
105 second chassis
C₂ power storage element
D₂ rectifier element
R₂, R₃ resistance element

What is claimed is:

1. An information processing apparatus comprising:
a controller; and
an audio system, wherein
the controller is configured to,
when connection between the audio system and a sound source is detected,
measure an output level of a test signal output to the sound source, and
determine an output gain of a voice signal output from the audio system to the sound source based on the output level.

2. The information processing apparatus according to claim 1, wherein
the controller determines the output gain based on an impedance of the sound source corresponding to the output level, a rated power consumption of the sound source, and an internal resistance of the audio system.

3. The information processing apparatus according to claim 2, wherein
the controller determines a maximum voltage of the voice signal based on the impedance of the sound source, a maximum power consumption of the sound source and the internal resistance.

4. The information processing apparatus according to claim 1, wherein
the test signal has a frequency component having a frequency higher than an audible band.

5. The information processing apparatus according to claim 4, further comprising:
a rectifier element configured to rectify the test signal and output a rectified signal; and
a low pass filter configured to extract a low pass signal from the rectified signal, wherein
the controller measures an output level of the low pass signal.

6. The information processing apparatus according to claim 5, wherein
the low pass filter includes a resistance element and a power storage element in parallel with the controller,
the controller is configured to detect the output level after a predetermined time has elapsed from output start of the test signal, and
the predetermined time is set to a value larger than a product of a resistance value of the resistance element and an electrostatic capacity of the power storage element.

7. A control method of an information processing apparatus including a controller and an audio system, the control method comprising:
causing the controller to execute,
when connection between the audio system and a sound source is detected,
a step of measuring an output level of a test signal output to the sound source; and
a step of determining an output gain of a voice signal output from the audio system to the sound source based on the output level.
